(19) United States
(12) Patent Application Publication
(10) Pub. No.: US 2026/0231402 A1
(43) Pub. Date: Aug. 6, 2026

(54) HIGH-DENSITY ONE-TIME PROGRAMMABLE MEMORY

(71) Applicant: Sichuan Kiloway Technologies Co., Ltd., Mianyang City (CN)

(72) Inventors: Junhua MAO, Mianyang City (CN); Jack Zezhong PENG, Mianyang City (CN)

(21) Appl. No.: 19/529,885

(22) Filed: Feb. 4, 2026

(30) Foreign Application Priority Data
Feb. 6, 2025 (CN) 202510131756.8

(51) Int. Cl. H10B 20/25

(52) U.S. Cl. CPC H10B 20/25

(57) ABSTRACT

A high-density one-time programmable memory is provided, which includes an array formed by arranging M×N memory cells, M and N are predetermined natural numbers. A memory cell includes an anti-fuse storage transistor and a selection transistor. The selection transistor includes a source region with a second conductivity type, a drain region with a second conductivity type and a substrate with a first conductivity type, where the source region of the selection transistor includes a second conductivity type region and a second-conductivity-type lightly doped region, and the drain region only has a second conductivity type region. The doping concentrations of the second conductivity type regions of the source region and the drain region are the same, and a doping concentration of the second-conductivity-type lightly doped region is lower than that of the second conductivity type region.

### CROSS-REFERENCE TO RELATED APPLICATION

This patent application claims the benefit and priority of Chinese Patent Application No. 202510131756.8 filed with the China National Intellectual Property Administration on February 06, 2025, the disclosure of which is incorporated by reference herein in its entirety as part of the present application.

### TECHNICAL FIELD

The present disclosure relates to an integrated circuit technology, and in particular, to a memory technology.

### BACKGROUND

Patent documents CN1351380A, US8259518B2, and CN1983449A disclose anti-fuse memory technologies based on Metal Oxide Semiconductor (MOS) transistors. FIG. 1 shows a MOS transistor structure in a Prior art. Gate-Induced Drain Leakage (GIDL) breakdown voltage of a traditional Metal-Oxide-Semiconductor Field Effect Transistor (MOSFET) is relatively low. GIDL is gate-induced drain leakage current, which occurs below a gate-drain overlap region. In a traditional Complementary Metal Oxide Semiconductor (CMOS), a Lightly Doped Drain (LDD) provides a short connection path under a side wall between an inversion channel below a Gate and a drain. Because an LDD region and the Gate are extremely close to each other, and even overlap with each other from a projection perspective. Under relatively high Gate-Drain (G-D) reverse voltage, the Gate has to be aligned with a source-drain in device structure, but it is impossible to absolutely align the Gate with the source-drain, so an overlap is inevitable. For an overlap region of a Drain and the Gate (using a N-Channel Metal Oxide Semiconductor (NMOS) as an example), when negative bias voltage is applied to the gate or strong positive bias voltage is applied to the drain, holes of majority carriers, serving as a substrate, accumulate near a drain LDD on a surface and deplete/deeply deplete original N-type silicon, tending to invert the region. As a result, a depletion region of the drain LDD extends to the drain, achieving an effect like p+ doping, and occurring strong band bending due to an induced electric field. In this case, when the band bending becomes greater than a band gap, that is, when a valence band Ev becomes higher than a conduction band Ec, electrons flow into the drain through a tunneling effect and generate leakage current. Due to Electron-Hole Pairs (EHPs) generated by heat, holes flow into the substrate and electrons flow into the drain, thereby increasing the leakage current. In addition, if a device deteriorates due to Negative Bias Temperature Instability (NBTI), Positive Bias Temperature Instability (PBTI), or Hot Carrier Injection (HCI) stress, traps in an interface will generate trap-assisted tunneling current to further increase GIDL current, and the GIDL leakage current is formed by various factors.

US patent document US20090090980A1 discloses an asymmetric LDD-type MOS transistor that is compatible with a standard CMOS technology and does not require an additional mask. To create a region with large voltage drop on a drain side, the drain LDD is removed by blocking LLD/Halo injection. Forming LDD/Halo injection through a mask tool only requires one logic operation layer, so additional process steps are not required. Significant improvement of a drain breakdown voltage (BVdss) is the design of a wide depletion region below a sidewall region and between the drain and substrate, which reduces a peak electric field on a drain side and can support higher reverse bias drain voltage than that in traditional cases.

### SUMMARY

A technical problem to be solved by the present disclosure is to provide a high-density one-time programmable memory with a simple structure and a small size.

A technical solution adopted by the present disclosure to solve the technical problem is that a high-density one-time programmable memory includes an array formed by arranging M×N memory cells, where M and N are predetermined natural numbers. A memory cell includes an anti-fuse storage transistor and a selection transistor. A gate of the anti-fuse storage transistor is connected to a first word line WP, a gate of the selection transistor is connected to a second word line WS, a first current end of the selection transistor is connected to a second current end of the anti-fuse storage transistor, and a second current end of the selection transistor is connected to a first bit line BL. The selection transistor includes a source region with a second conductivity type, a drain region with a second conductivity type and a substrate with a first conductivity type, where the source region of the selection transistor includes a second conductivity type region and a second-conductivity-type lightly doped region, the drain region only has a second conductivity type region, a doping concentration of the second conductivity type region in the source region is same as that of the second conductivity type region in the drain region, and a doping concentration of the second-conductivity-type lightly doped region is lower than that of the second conductivity type region.

Further, the memory cell further includes a detection MOS transistor, and where a connection point between the selection transistor and the anti-fuse storage transistor is connected to a gate of the detection MOS transistor, a first current end of the detection transistor is connected to the first bit line BL, and a second current end of the detection transistor is connected to a second bit line BR.

Further, the second current end of the detection transistor is connected to the second bit line BR through an isolation transistor, and a gate of the isolation transistor is connected to a third word line WR.

Further, the anti-fuse storage transistor is a native MOS transistor.

The present disclosure has the following beneficial effects. Through simulation comparison, for a 16×16 memory cell array, when all cells are 0, the static leakage current can be reduced by about 11% by adopting a solution of the present disclosed compared with using an original solution; and after all cells are 1, the static leakage current can be reduced by about 41% by adopting the solution of the present disclosed compared with using the original solution. It can be seen that, under a condition of limited power consumption for writing, the present disclosure has lower load leakage current, thereby improving write voltage and achieving higher write yield.

### BRIEF DESCRIPTION OF THE DRAWINGS

FIG. 1 is a schematic structural diagram of a MOS transistor.

FIG. 2 is a schematic structural diagram of an asymmetric MOS transistor used by the present disclosure.

FIG. 3 is a circuit diagram of Embodiment 1 of the present disclosure.

FIG. 4 is a circuit diagram of Embodiment 2 of the present disclosure.

FIG. 5 is a circuit diagram of Embodiment 3 of the present disclosure.

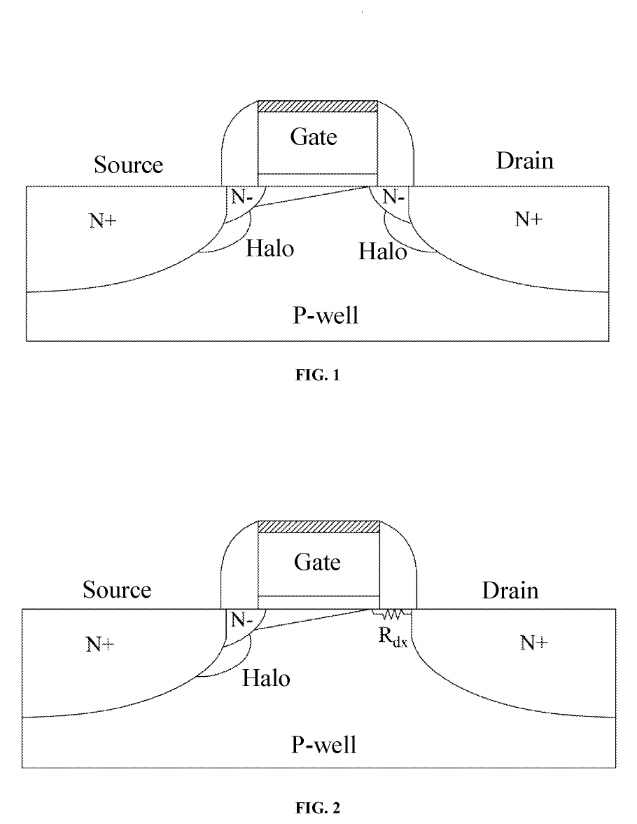

### DETAILED DESCRIPTION OF THE EMBODIMENTS

A high-density one-time programmable memory includes an array formed by arranging M×N memory cells, where M and N are predetermined natural numbers. A memory cell includes an anti-fuse storage transistor and a selection transistor. A gate of the anti-fuse storage transistor is connected to a first word line WP, a gate of the selection transistor is connected to a second word line WS, a first current end of the selection transistor is connected to a second current end of the anti-fuse storage transistor, and a second current end of the selection transistor is connected to a first bit line BL. The selection transistor includes a source region with a second conductivity type, a drain region with a second conductivity type and a substrate with a first conductivity type. The source region of the selection transistor includes a second conductivity type region and a second-conductivity-type lightly doped region, and the drain region only has a second conductivity type region. The doping concentration of the second conductivity type region in the source region is same as that of the second conductivity type region in the drain region, and a doping concentration of the second-conductivity-type lightly doped region is lower than that of the second conductivity type region. The number of the anti-fuse storage transistor may be one, and the number of the selection transistor may be one. In some embodiments, the memory cell further includes a detection MOS transistor, and where a connection point between the selection transistor and the anti-fuse storage transistor is connected to a gate of the detection MOS transistor, a first current end of the detection transistor is connected to the first bit line BL, and a second current end of the detection transistor is connected to a second bit line BR. The number of the detection MOS transistor may be one.

For example, the gate of the anti-fuse storage transistor is connected to the first word line WP, the gate of the selection transistor is connected to the second word line WS, the first current end (drain end) of the selection transistor is connected to the second current end (a source end) of the anti-fuse storage transistor, and the second current end (source end) of the selection transistor is connected to the first bit line BL. The selection transistor includes the source region with the second conductivity type (N-type doping), the drain region with the second conductivity type (N-type doping) and the substrate with the first conductivity type (P-type doping). The source region of the selection transistor includes the second conductivity type region (N+ region) and the second-conductivity-type lightly doped region (N- region). The drain region only has the second conductivity type region (N+ region). The doping concentrations of the second conductivity type regions (N+ regions) of the source region and the drain region are the same, and the doping concentration of the second-conductivity-type lightly doped region (N- region) is lower than that of the second conductivity type region (N+ region).

### Embodiment 1

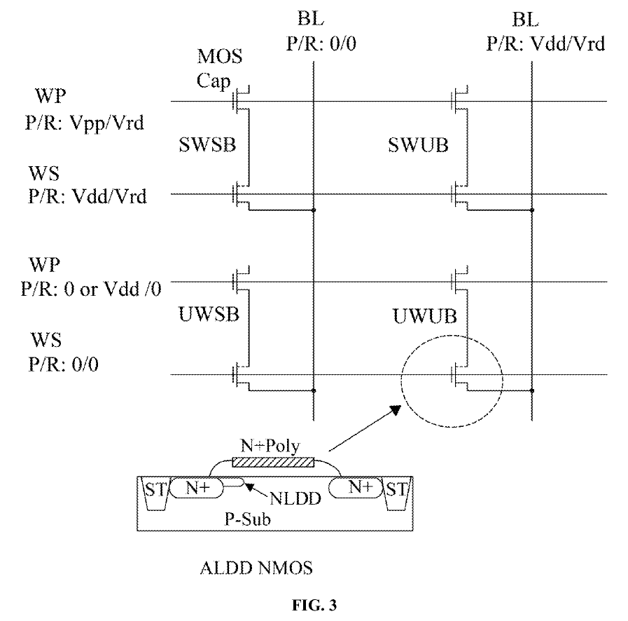

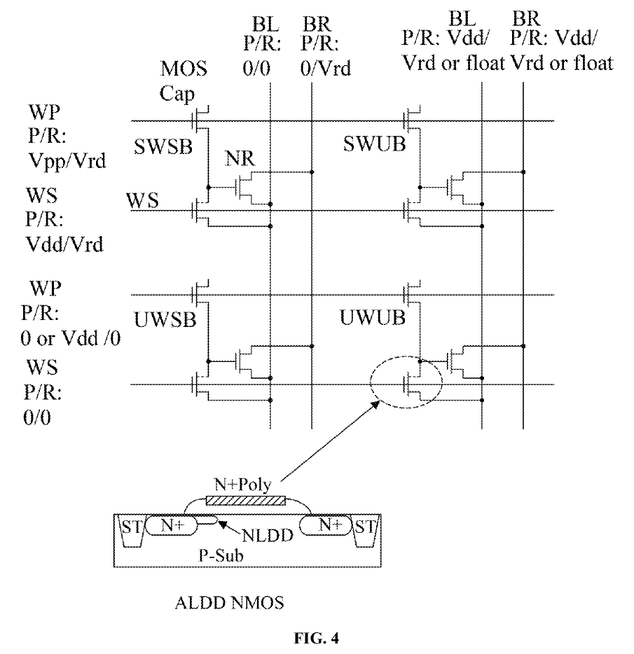

Referring FIG. 3, a circuit shown in FIG. 3 is an improved circuit based on a circuit in Chinese Patent Document CN1351380A. A selection transistor (shown in a dashed part) is improved in this embodiment, and a MOS transistor with an asymmetric LDD (ALDD) structure is used as the selection transistor. A source region of the selection transistor includes a second conductivity type region (N+ region) and a second-conductivity-type lightly doped region (N- region, that is NLDD); and a drain region only has a second conductivity type region (N+ region), and the drain is not provided with the second-conductivity-type lightly doped region (N- region).

As further improvement of Embodiment 1, the anti-fuse storage transistor may adopt a native MOS transistor because the native MOS transistor has lower threshold voltage than that of a conventional MOS transistor. A dielectric between a gate of the programmed storage transistor and a channel forms high resistance conduction between a gate and a channel due to breakdown, conduction between the channel and a source depends on formation of the channel, and detection current can reach a detection circuit through the gate-channel-source only in the existence of both the conduction between the gate and the channel and the conduction between the channel and the source. A channel can be formed only when voltage applied between the gate and the source of the MOS transistor is higher than threshold voltage, and voltage obtained at the source has a voltage drop loss of a threshold compared with gate voltage. By adopting the native MOS transistor, a voltage drop loss caused by threshold voltage of the storage transistor when detection current flows through the storage transistor can be reduced. Under the same excitation voltage, higher detection current can be obtained, and detection sensitivity is improved; or under a requirement for the same detection sensitivity, excitation voltage required for detection can be reduced.

### Embodiment 2

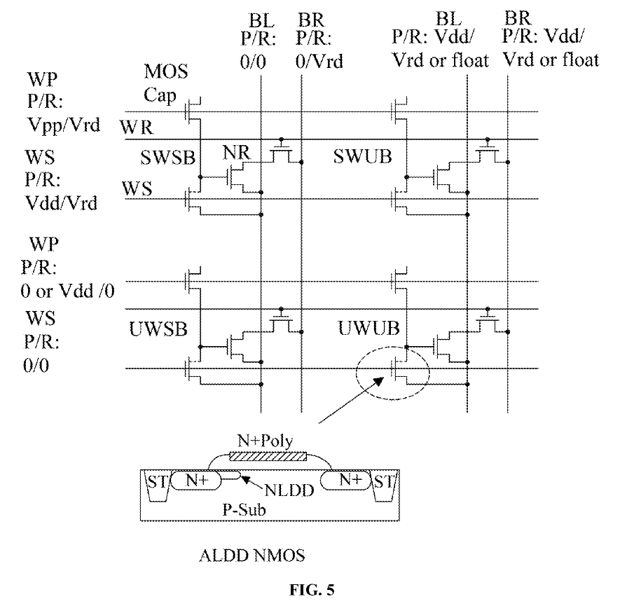

Referring FIG. 4, a memory cell shown in FIG. 4 is an improved memory cell based on a memory cell in US Patent Document US8797820B2. A selection transistor (shown in a dashed part) is improved in this embodiment, and a MOS transistor with an asymmetric LDD structure is used as the selection transistor. A source region of the selection transistor includes a second conductivity type region (N+ region) and a second-conductivity-type lightly doped region (N- region); and a drain region only has a second conductivity type region (N+ region), and the drain is not provided with the second-conductivity-type lightly doped region (N- region).

### Embodiment 3

Referring FIG. 5, a memory cell shown in FIG. 5 is an improved memory cell based on a memory cell in Chinese Patent Document CN1983449A. A selection transistor (shown in a dashed part) is improved in this embodiment, and a MOS transistor with an asymmetric LDD structure is used as the selection transistor. A source region of the selection transistor includes a second conductivity type region (N+ region) and a second-conductivity-type lightly doped region (N- region); and a drain region only has a second conductivity type region (N+ region), and the drain is not provided with the second-conductivity-type lightly doped region (N- region).

As further improvement of Embodiment 2 and Embodiment 3, a native MOS transistor is adopted as an anti-fuse storage transistor because the native MOS transistor has lower threshold voltage than that of a conventional MOS transistor. A dielectric between a gate of the programmed storage transistor and a channel forms high resistance conduction between a gate and a channel due to breakdown, conduction between the channel and a source depends on formation of the channel, and detection current can reach a detection circuit through the gate-channel-source only in the existence of both the conduction between the gate and the channel and the conduction between the channel and the source. A channel can be formed and conducted only when voltage applied between the gate and the source of the MOS transistor is higher than threshold voltage, and voltage obtained at the source has a voltage drop loss of a threshold compared with gate voltage. By adopting the native MOS transistor, the storage transistor can reduce a voltage drop loss caused by threshold voltage of the storage transistor when detection current flows through the storage transistor, thereby obtaining higher detection voltage at the gate of the detection transistor NR, and reducing excitation voltage required for detection.

What is claimed is:

1. A one-time programmable memory, comprising an array formed by arranging M×N memory cells, M and N being predetermined natural numbers, wherein each memory cell comprises an anti-fuse storage transistor and a selection transistor, wherein
a gate of the anti-fuse storage transistor is connected to a first word line WP, a gate of the selection transistor is connected to a second word line WS, a first current end of the selection transistor is connected to a second current end of the anti-fuse storage transistor, and a second current end of the selection transistor is connected to a first bit line BL; and
the selection transistor comprises a source region with a second conductivity type, a drain region with the second conductivity type and a substrate with a first conductivity type, wherein the source region of the selection transistor comprises a second conductivity type region and a second-conductivity-type lightly doped region, the drain region only has a second conductivity type region, a doping concentration of the second conductivity type region in the source region is same as that of the second conductivity type region in the drain region, and a doping concentration of the second-conductivity-type lightly doped region is lower than that of the second conductivity type region.

2. The one-time programmable memory according to claim 1, wherein each memory cell further comprises a detection Metal Oxide Semiconductor (MOS) transistor, and wherein a connection point between the selection transistor and the anti-fuse storage transistor is connected to a gate of the detection MOS transistor, a first current end of the detection MOS transistor is connected to the first bit line BL, and a second current end of the detection MOS transistor is connected to a second bit line BR.

3. The one-time programmable memory according to claim 2, wherein the second current end of the detection MOS transistor is connected to the second bit line BR through an isolation transistor, and a gate of the isolation transistor is connected to a third word line WR.

4. The one-time programmable memory according to claim 1, wherein the anti-fuse storage transistor is a native MOS transistor.

5. The one-time programmable memory according to claim 2, wherein the anti-fuse storage transistor is a native MOS transistor.

6. The one-time programmable memory according to claim 3, wherein the anti-fuse storage transistor is a native MOS transistor.
